(19) United States
(12) Patent Application Publication
(10) Pub. No.: US 2026/0025013 A1
(43) Pub. Date: Jan. 22, 2026

(54) BATTERY MANAGEMENT APPARATUS AND OPERATING METHOD THEREOF

(71) Applicant: LG ENERGY SOLUTION, LTD., Seoul (KR)

(72) Inventor: Sung Gun LEE, Daejeon (KR)

(73) Assignee: LG ENERGY SOLUTION, LTD., Seoul (KR)

(21) Appl. No.: 18/998,361

(22) PCT Filed: Aug. 9, 2023
(86) PCT No.: PCT/KR2023/011775

§ 371 Date: Jan. 24, 2025

(30) Foreign Application Priority Data
Sep. 27, 2022 (KR) 10-2022-0122898

(51) Int. Cl. H02J 7/00; H01M 10/42

(52) U.S. Cl. CPC H02J 7/0029; H01M 10/425; H02J 7/0016; H02J 7/0047; H01M 2010/4271; H01M 2010/4278

(57) ABSTRACT

An aspect of the current disclosure includes a battery management apparatus including a plurality of resistors respectively connected to a plurality of batteries, respectively, a plurality of first switches configured to respectively connect the plurality of resistors to output terminals of the plurality of batteries, respectively, a plurality of second switches configured to connect the plurality of resistors to each other in parallel, and a controller configured to determine whether each of the plurality of batteries is abnormal, and control operations of the plurality of first switches and the plurality of second switches based on whether each battery of the plurality of batteries is abnormal.

### CROSS-REFERENCE TO RELATED APPLICATION

This application claims priority to and the benefit of Korean Patent Application No. 10-2022-0122898 filed in the Korean Intellectual Property Office on Sep. 27, 2022, the entire contents of which are incorporated herein by reference.

### TECHNICAL FIELD

Embodiments disclosed herein relate to a battery management apparatus and an operating method thereof.

### BACKGROUND ART

Recently, research and development of secondary batteries have been actively performed. Secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

To further increase the usability and portability of the lithium-ion battery, a battery swapping service has been provided. However, when some of the batteries in a battery swapping station catch fire, chain ignition may occur to nearby batteries, causing all batteries in the battery swapping station to burn out.

A discharge rate of the igniting battery may be raised to prevent the chain ignition of the battery swapping station, but the discharge rate of the battery may be determined and fixed by a resistance value of a discharge resistor connected to the battery, such that the discharge resistor needs to be changed to adjust the discharge rate.

### DISCLOSURE

### Technical Problem

Embodiments disclosed herein provide a battery management apparatus and an operating method thereof in which a discharge rate and/or heating of a battery may be controlled using a plurality of resistors connected to one another in parallel.

Technical problems of the embodiments disclosed herein are not limited to the above-described technical problems, and other unmentioned technical problems would be clearly understood by one of ordinary skill in the art from the following description.

### Technical Solution

A battery management apparatus according to an aspect disclosed herein includes a plurality of resistors connected to a plurality of batteries, respectively, a plurality of first switches configured to connect the plurality of resistors to output terminals of the plurality of batteries, respectively, a plurality of second switches configured to connect the plurality of resistors to each other in parallel, and a controller configured to determine whether each battery of the plurality of batteries is abnormal, and control operations of the plurality of first switches and the plurality of second switches based on whether each battery of the plurality of batteries is abnormal.

In an aspect of the disclosure, the plurality of resistors may be connected to the plurality of batteries in parallel, respectively, and the plurality of second switches may be connected to one another in series.

In an aspect of the disclosure, the battery management apparatus may further include a communication unit configured to receive an abnormality signal of the plurality of batteries from a battery management system (BMS) for each battery of the plurality of batteries, in which the controller is further configured to determine a first battery for which an abnormality signal is sensed and at least one second battery connected to the first battery among the plurality of batteries, based on the abnormality signal.

In an aspect of the disclosure, the controller may be further configured to obtain temperature information of each battery of the plurality of batteries from a plurality of temperature measurement sensors that measure temperatures of the plurality of batteries, respectively, and determine a first battery for which an abnormal temperature is sensed and at least one second battery connected to the first battery among the plurality of batteries, based on the temperature information.

In an aspect of the disclosure, the controller may be further configured to determine the at least one second battery adjacent to the first battery based on an arrangement order of each battery of the plurality of batteries, when sensing the abnormal temperature or the abnormality signal of the first battery among the plurality of batteries.

In an aspect of the disclosure, the controller may be further configured to calculate a capacity of the first battery and a capacity of the at least one second battery and compare the capacity of the first battery with the capacity of the second battery to control operations of the plurality of first switches and the plurality of second switches.

In an aspect of the disclosure, when the capacity of the first battery exceeds the capacity of the at least one second battery, the controller may be further configured to turn on a first switch among the plurality of first switches for connecting the first battery to a resistor connected to the first battery and turn on at least any one second switch among the plurality of second switches.

In an aspect of the disclosure, when the capacity of the first battery is less than the capacity of the at least one second battery, the controller may be further configured to turn on a first switch among the plurality of first switches for connecting the at least one second battery to a resistor connected to the at least one second battery and turn on at least one second switch among the plurality of second switches.

An operating method of a battery management apparatus according to an aspect disclosed herein includes determining whether each battery of a plurality of batteries is abnormal, controlling operations of a plurality of first switches for connecting a plurality of resistors connected to the plurality of batteries to battery current output terminals of the plurality of batteries, respectively, based on whether each battery of the plurality of batteries is abnormal, and controlling operations of a plurality of second switches connecting the plurality of resistors in parallel, respectively.

In an aspect of the disclosure, the determining of whether each battery of the plurality of batteries is abnormal may include receiving an abnormality signal of the plurality of batteries from a battery management system (BMS) for each battery of the plurality of batteries, and determining a first battery for which the abnormality signal is sensed and at least one second battery connected to the first battery among the plurality of batteries, based on the abnormality signal.

In an aspect of the disclosure, the determining of whether each battery of the plurality of batteries is abnormal may further include obtaining temperature information of the plurality of batteries from a plurality of temperature measurement sensors that measure temperatures of the plurality of batteries, respectively, and determining a first battery for which an abnormal temperature is sensed and at least one second battery connected to the first battery among the plurality of batteries, based on the temperature information.

In an aspect of the disclosure, the determining of whether each battery of the plurality of batteries is abnormal may further include determining the at least one second battery adjacent to the first battery based on an arrangement order of the plurality of batteries, when sensing the abnormal temperature or the abnormality signal of the first battery among the plurality of batteries.

In an aspect of the disclosure, the determining of whether each battery of the plurality of batteries is abnormal may further include calculating a capacity of the first battery and a capacity of the at least one second battery and comparing the capacity of the first battery with the capacity of the at least one second battery to control operations of the plurality of first switches and the plurality of second switches.

In an aspect of the disclosure, the controlling of the operations of the plurality of first switches for connecting the plurality of resistors connected to the plurality of batteries to the battery current output terminals of the plurality of batteries, based on whether each battery of the plurality of batteries is abnormal may include, when the capacity of the first battery exceeds the capacity of the at least one second battery, turning on a first switch among the plurality of first switches for connecting the first battery to a resistor connected to the first battery, and the controlling of the operations of the plurality of second switches connecting the plurality of resistors in parallel may include turning on at least one second switch among the plurality of second switches.

In an aspect of the disclosure, the controlling of the operations of the plurality of first switches for connecting the plurality of resistors connected to the plurality of batteries to the battery current output terminals of the plurality of batteries, based on whether each battery of the plurality of batteries is abnormal may further include, when the capacity of the first battery is less than the capacity of the at least one second battery, turning on a first switch among the plurality of first switches for connecting the second battery to a resistor connected to the second battery, and the controlling of the operations of the plurality of second switches connecting the plurality of resistors in parallel may include turning on at least one second switch among the plurality of second switches.

### Advantageous Effects

A battery management apparatus and an operating method thereof according to an embodiment disclosed herein may control a discharge rate and/or heating of a battery by using a plurality of resistors connected to one another in parallel.

Moreover, the battery management system and the operating method thereof according to an embodiment disclosed herein may stably manage the lifespan of a battery.

### DESCRIPTION OF DRAWINGS

FIG. 1 is a diagram conceptually showing a battery swapping station according to an embodiment disclosed herein.

FIG. 2 is a diagram conceptually showing a battery swapping station according to another embodiment disclosed herein.

FIG. 3 is a block diagram of a battery management apparatus according to an embodiment disclosed herein.

FIG. 4 is a circuit diagram for describing an operation of a battery management apparatus, according to an embodiment disclosed herein.

FIG. 5 is a flowchart of an operating method of a battery management apparatus according to an embodiment disclosed herein.

FIG. 6 is a flowchart showing an operating method of a battery management apparatus, according to another embodiment disclosed herein.

FIG. 7 is a block diagram showing a hardware configuration of a computing system for performing an operating method of a battery management apparatus, according to an embodiment disclosed herein.

### MODE FOR INVENTION

Hereinafter, embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present application.

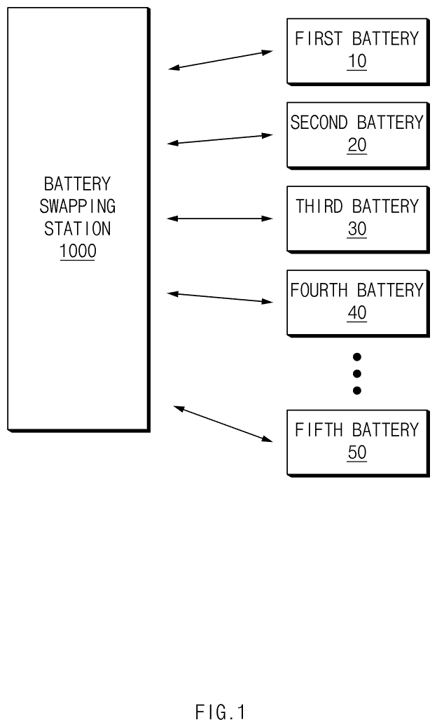

FIG. 1 is a diagram conceptually showing a battery swapping station according to an embodiment disclosed herein.

Referring to FIG. 1, a battery swapping station (BSS) 1000 may provide an overall management service for evaluation, measurement, charge, exchange, etc., of a battery, and in the present disclosure, a function of the battery swapping station 1000 will be described based on a battery swapping service. Herein, the battery swapping service may mean a service that analyzes states of a plurality of batteries 10, 20, 30, 40, and 50 that are service subjects and swaps the batteries 10, 20, 30, 40, and 50 with other batteries 10, 20, 30, 40, and 50 according to an analysis result. Such swapping may be automatically performed by a manager and/or user's setting. For example, the battery swapping station 1000 may provide a user with a battery swapping service by collecting the batteries 10, 20, 30, 40, and 50 returned from the user and providing other previously charged batteries 10, 20, 30, 40, and 50 to the user.

Herein, the batteries 10, 20, 30, 40, and 50 may be devices mounted on a subject device (e.g., an electrical transportation such as an electrical vehicle, an electrical scooter, an electrical bike, etc.) to supply power for driving the subject device, and may be implemented in the form of battery packs. The battery pack may include a battery that stores power and a battery management system (BMS) that controls an operation of the battery. The battery may include at least one battery cell for storing power under control of the BMS. The battery cell, which is a basic unit of a battery available by charging and discharging electrical energy, may be a lithium ion (Li-ion) battery, an Li-ion polymer battery, a nickel-cadmium (Ni—Cd) battery, a nickel hydrogen (Ni-MH) battery, etc., and is not limited thereto. The BMS may control charge and discharge of the battery, and collect data that is a basis for state analysis of the battery and transmit the data to an external device at the request of the external device.

Hereinbelow, a description will be made assuming that the plurality of batteries 10, 20, 30, 40, and 50 are implemented in the form of battery packs. While it is illustrated in FIG. 1 that the number of batteries 10, 20, 30, 40, and 50 is 5, the batteries may include n batteries (n is a natural number greater than or equal to 2).

Depending on an embodiment, the battery swapping station 1000 may be arranged in a service station where the battery swapping service is provided or in a space that is separate from the service station.

The battery swapping station 1000 may analyze the states of the plurality of batteries 10, 20, 30, 40, and 50 connected thereto and swap the batteries 10, 20, and 30 with other batteries 10, 20, and 30 or reuse (i.e., not swap) the batteries 10, 20, and 30, according to a result of state analysis. The battery swapping station 1000 may autonomously determine whether state analysis with respect to the plurality of batteries 10, 20, 30, 40, and 50 and/or swapping of the batteries 10, 20, and 30 are required, but according to another embodiment, at least some operation may be performed in association with a server (e.g., a cloud server) connected through a network. For example, the battery swapping station 1000 may transmit to the cloud server, information that is a basis for determining whether swapping of a battery is required, and the cloud server may transmit to the battery swapping station 1000, the information about whether swapping of the battery is required.

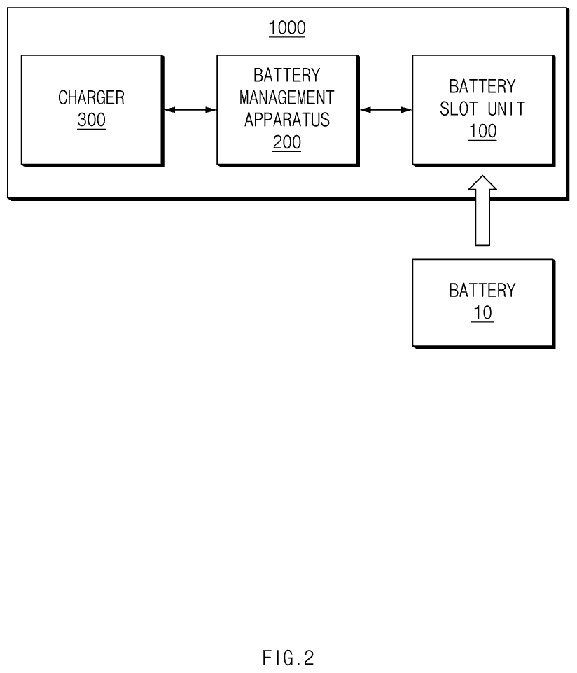

FIG. 2 is a diagram conceptually showing a battery swapping station according to another embodiment disclosed herein.

Referring to FIG. 2, the battery swapping station 1000 may include a battery slot unit 100, a battery management apparatus 200, and a charger 300.

The battery slot unit 100 may accommodate the plurality of batteries 10, 20, 30, 40, and 50 connected. The battery slot unit 100 may include a plurality of battery slots that respectively accommodate the plurality of batteries connected. The battery slot unit 100 may be connected to the battery management apparatus 200. The plurality of batteries 10, 20, 30, 40, and 50 accommodated in the battery slot unit 100 may be physically controlled based on a control signal of the battery management apparatus 200.

The battery management apparatus 200 may manage and/or control a state and/or an operation of the plurality of batteries 10, 20, 30, 40, and 50. The battery management apparatus 200 may manage charge and/or discharge of the plurality of batteries 10, 20, 30, 40, and 50.

In addition, the battery management apparatus 200 may monitor a voltage, a current, a temperature, etc., of each of the plurality of batteries 10, 20, 30, 40, and 50. The battery management apparatus 200 may calculate parameters indicating the states of the plurality of batteries 10, 20, 30, 40, and 50 based on measurement values of the monitored voltage, current, temperature, etc.

The battery management apparatus 200 may manage a state of charge (SoC) and/or a state of health (SoH) of the plurality of batteries 10, 20, 30, 40, and 50. The battery management apparatus 200 may receive SoC information of each of the plurality of batteries 10, 20, 30, 40, and 50 from the corresponding batteries 10, 20, 30, 40, and 50. Herein, the SoC information may indicate a current SoC of the corresponding battery and the SoC may mean a charge state of a battery included in the battery, i.e., a remaining capacity rate. A BMS for the corresponding battery may calculate the remaining capacity rate by dividing the current available capacity of the battery by a total capacity of the battery. For example, the remaining capacity rate may be calculated as a percentage. According to another embodiment, the battery management apparatus 200 may obtain SoC information by directly calculating a remaining capacity rate for a battery of the battery without receiving the SoC information from the BMS for the battery.

The charger 300 may charge each of the plurality of batteries 10, 20, 30, 40, and 50 under control of the battery management apparatus 200. The charger 300 may be supplied with power from an external utility power source to convert the power into a power form that may be received by the plurality of batteries 10, 20, 30, 40, and 50, and supply the power to the plurality of batteries 10, 20, 30, 40, and 50. According to an embodiment, the charger 300 may supply power until the SoCs of the plurality of batteries 10, 20, 30, 40, and 50 reach 100%, thus fully charging the plurality of batteries 10, 20, 30, 40, and 50.

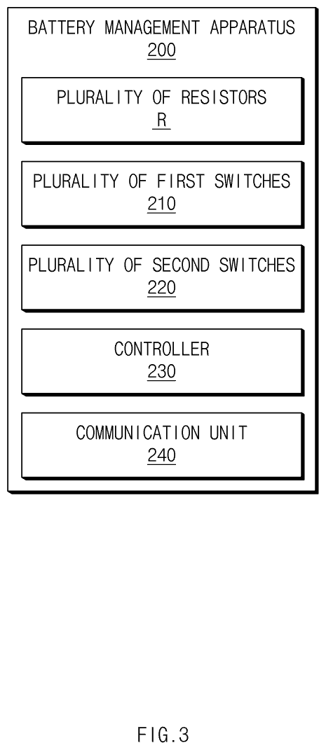

Hereinbelow, a configuration and an operation of the battery management apparatus 200 will be described in more detail with reference to FIG. 3.

FIG. 3 is a block diagram of a battery management apparatus according to an embodiment disclosed herein.

Referring to FIG. 3, the battery management apparatus 200 may include a plurality of resistors R, a plurality of first switches 210, a plurality of second switches 220, a controller 230, and a communication unit 240.

When any one of the plurality of batteries 10, 20, 30, 40, and 50 is the battery management apparatus 200 ignites, the battery management apparatus 200 may discharge an igniting battery or a nearby battery to remove fuel that is an energy source of the igniting battery or the nearby battery so as to suppress the spread of heat to the nearby battery or all the batteries. The battery management apparatus 200 may respectively connect the plurality of resistors R to the exterior of the plurality of batteries 10, 20, 30, 40, and 50 and apply discharge current to each resistor to discharge the batteries.

Herein, the discharge rate of the battery may be determined by the resistance value of the plurality of resistors R, and the resistance value needs to be changed to adjust the discharge rate of the battery. Thus, the battery management apparatus 200 may connect the plurality of resistors R in parallel and distribute discharge current to the plurality of resistors R connected in parallel to adjust the discharge current value, thus controlling the discharge rate.

The plurality of resistors R may be serially connected to the plurality of batteries 10, 20, 30, 40, and 50. In addition, the plurality of resistors R may be respectively connected to the plurality of first switches 210 in series. More specifically, as the plurality of first switches 210 are turned on, the plurality of resistors R may be respectively connected in series to the plurality of batteries 10, 20, 30, 40, and 50 serially connected to the first switches 210, thus discharging the batteries.

The plurality of resistors R may be connected to one another in parallel, and may be selectively connected in parallel based on the plurality of first switches 210 respectively connected thereto being turned on/off. More specifically, as any one of the plurality of first switches 210 respectively connected in series to the plurality of resistors R is selectively turned on, the resistors R connected to the plurality of first switches 210 in the on state among the plurality of resistors R connected in parallel may be connected to one another in parallel.

That is, some of the plurality of resistors R may be selectively connected in parallel based on the plurality of first switches 210 being on or off. Thus, resistance values of the plurality of resistors R may be changed, such that discharge rates of the plurality of batteries 10, 20, 30, 40, and 50 may be changed.

The plurality of first switches 210 may respectively connect the plurality of resistors R to output terminals of the plurality of batteries 10, 20, 30, 40, and 50. The plurality of first switches 210 may be respectively connected to the plurality of batteries 10, 20, 30, 40, and 50 in series. The plurality of first switches 210 may be respectively connected to the plurality of resistors R in series.

Each of the plurality of first switches 210 may receive a control signal from the controller 230, thus being turned on or off.

The plurality of second switches 220 may be connected to the plurality of resistors R in parallel. The plurality of second switches 220 may be serially connected to one another. Each of the plurality of second switches 220 may receive a control signal from the controller 230, thus being turned on or off.

The communication unit 240 may wiredly and/or wirelessly communicate with a BMS for each of the plurality of batteries 10, 20, 30, 40, and 50. For example, the communication unit 240 may communicate with a BMS for each of the plurality of batteries 10, 20, 30, 40, and 50 according to a differential input communication protocol. Herein, examples of the differential input communication protocol may include a controller area network (CAN). In addition, the communication unit 240 may communicate with a BMS for each of the plurality of batteries 10, 20, 30, 40, and 50 according to a wireless communication protocol such as WiFi (a registered trademark), Bluetooth (a registered trademark), etc.

According to an embodiment, the communication unit 240 may periodically communicate with a BMS for each of the plurality of batteries 10, 20, 30, 40, and 50. When a BMS for any one of the plurality of batteries 10, 20, 30, 40, and 50 does not transmit a communication signal after an elapse of a specific period, the communication unit 240 may transmit a communication signal to the BMS for any one of the plurality of batteries 10, 20, 30, 40, and 50.

According to an embodiment, the communication unit 240 may receive an abnormality signal of the battery from the BMS for any one of the plurality of batteries 10, 20, 30, 40, and 50.

The controller 230 may determine whether each of the plurality of batteries 10, 20, 30, 40, and 50 is abnormal.

According to an embodiment, when the communication unit 240 does not receive a communication signal after an elapse of a specific period from a BMS for any one of the plurality of batteries 10, 20, 30, 40, and 50 and does not receive the communication signal even after repeatedly retrying transmission of a communication signal to the BMS for any one of the plurality of batteries 10, 20, 30, 40, and 50, the controller 230 may determine any one of the plurality of batteries 10, 20, 30, 40, and 50 to be an abnormal battery.

According to an embodiment, when the communication unit 240 receives an abnormality signal from any one of the plurality of batteries 10, 20, 30, 40, and 50, the controller 230 may determine the any one of the plurality of batteries 10, 20, 30, 40, and 50 to be an abnormal battery.

According to an embodiment, the controller 230 may receive temperature information of the plurality of batteries 10, 20, 30, 40, and 50 from a plurality of temperature measurement sensors mounted in the battery slot unit 100, and may determine any one of the plurality of batteries 10, 20, 30, 40, and 50 to be an abnormal battery when a temperature of the any one of the plurality of batteries 10, 20, 30, 40, and 50 exceeds a threshold temperature based on the temperature information.

For example, the controller 230 may determine, as the abnormal battery, the first battery 10 among the plurality of batteries 10, 20, 30, 40, and 50 for which an abnormal temperature or an abnormality signal is sensed. The controller 230 may determine at least one second battery 20 related to the first battery 10 determined as the abnormal battery. For example, the controller 230 may determine at least one second battery 20 adjacent to the first battery 10 based on a previously stored arrangement order of the plurality of batteries 10, 20, 30, 40, and 50.

The controller 230 may control operations of the plurality of first switches 210 and the plurality of second switches 220 based on whether the plurality of batteries 10, 20, 30, 40, and 50 are abnormal.

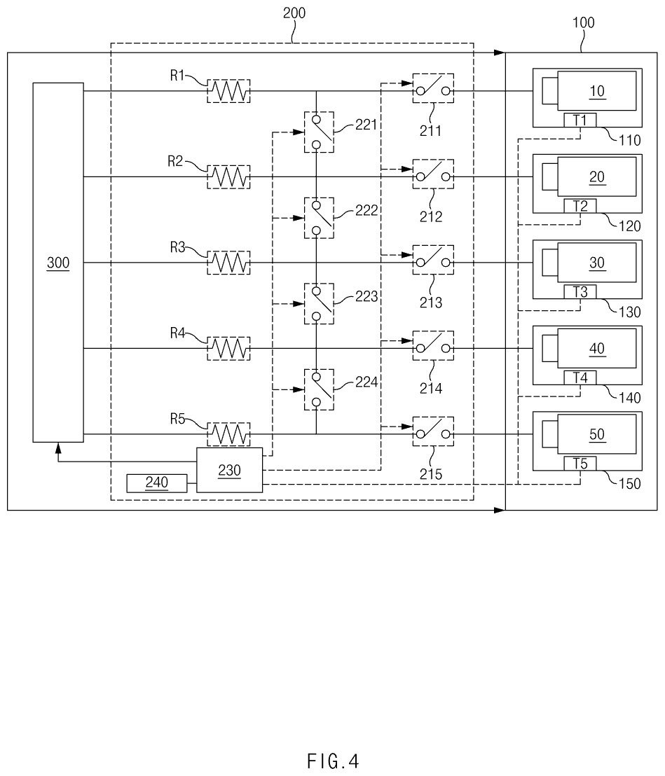

FIG. 4 is a circuit diagram for describing an operation of a battery management apparatus, according to an embodiment disclosed herein.

Hereinbelow, an operation of the battery management apparatus will be described in detail with reference to FIG. 4.

While it is shown in FIG. 4 that five batteries 10, 20, 30, 40, and 50 for receiving a battery swapping service are connected to the battery swapping station 1000, the scope of the present disclosure is not limited thereto and n batteries (n is a natural number of 2 or greater) for receiving the battery swapping service may be connected to the battery swapping station 1000.

Referring to FIG. 4, the battery slot unit 100 may include a plurality of battery slots 110, 120, 130, 140, and 150. Each of the plurality of battery slots 110, 120, 130, 140, and 150 may include any one of the plurality of batteries 10, 20, 30, 40, and 50.

The plurality of battery slots 110, 120, 130, 140, and 150 may respectively include temperature measurement sensors T1, T2, T3, T4, and T5. The plurality of temperature measurement sensors T1, T2, T3, T4, and T5 may measure temperatures of the plurality of batteries 10, 20, 30, 40, and 50. For example, the plurality of temperature measurement sensors T1, T2, T3, T4, and T5 may include a plurality of thermistors. A thermistor may mean a resistor having a resistance sensitively changing with a temperature, and the thermistor may measure a temperature by using a resistance change of a ceramic material with respect to a temperature. The temperature of the thermistor may increase due to occurrence of a self-heating phenomenon when current is applied thereto.

According to an embodiment, the controller 230 may obtain temperature information of the plurality of batteries 10, 20, 30, 40, and 50 from the plurality of temperature measurement sensors T1, T2, T3, T4, and T5 that measure the temperatures of the plurality of batteries 10, 20, 30, 40, and 50. For example, the controller 230 may determine, as the abnormal battery, the first battery 10 among the plurality of batteries 10, 20, 30, 40, and 50 for which an abnormal temperature is sensed.

In addition, for example, when the communication unit 240 does not receive a communication signal after an elapse of a specific period from a BMS for the first battery 10 of the plurality of batteries 10, 20, 30, 40, and 50 and does not receive the communication signal even after repeatedly retrying transmission of a communication signal to the BMS for the first battery 10, the controller 230 may determine the first battery 10 to be an abnormal battery.

In addition, for example, when the communication unit 240 receives an abnormality signal of the battery from the first battery 10 of the plurality of batteries 10, 20, 30, 40, and 50, the controller 230 may determine the first battery 10 as an abnormal battery.

When determining that the first battery 10 as an abnormal battery, the controller 230 may transmit a charge stop signal of the plurality of batteries 10, 20, 30, 40, and 50 to the charger 300.

The controller 230 may calculate capacities of the first battery 10 and the second battery 20. The controller 230 may receive battery data through communication with a BMS for the first battery 10 and a BMS for the second battery 20. Herein, the battery data may include, for example, a voltage of the battery, a voltage of a battery cell of the battery, a fault signal, an internal temperature of the battery, etc. The controller 230 may calculate capacities of the first battery 10 and the second battery 20 based on the battery data of the first battery 10 and the second battery 20.

The controller 230 may control operations of the plurality of first switches 210 and the plurality of second switches 220 by comparing the capacity of the first battery 10 with the capacity of the second battery 20.

According to an embodiment, when the capacity of the first battery 10 exceeds the capacity of the second battery 20, the controller 230 may discharge the first battery 10 until the capacity of the first battery 10 is equal to the capacity of the second battery 20. For example, when the capacity of the first battery 10 is 8000 mAh, a voltage of the first battery 10 is 60 V, the capacity of the second battery 20 is 4000 mAh, and a voltage of the second battery 20 is 50 V, the controller 230 may discharge the first battery 10 until the capacity of the first battery 10 is equal to the capacity of the second battery 20. The controller 230 may turn on, among the plurality of first switches 210, a first switch 211 for connecting the first battery 10 to a first resistor R1 connected to the first battery 10, and turn off the plurality of other first switches 212, 213, 214, and 215.

The controller 230 may turn on at least any one second switch of the plurality of second switches 220 to adjust a distribution ratio of discharge current of the first battery 10 applied to the plurality of resistors R.

For example, when the discharge current of the first battery 10 is 10 A and the voltage of the first battery 10 is 60 V, the controller 230 may turn on some of the plurality of second switches 220 and turn off some others to control the plurality of resistor R values to be 60 V/10 A=6 ohm.

For example, when a resistance value of each of the plurality of resistors R is 24 ohm, the controller 230 may connect a first resistor R1, a second resistor R2, a third resistor R3, and a fourth resistor R4 among the plurality of resistors R in parallel to control a total resistance value of the first resistor R1, the second resistor R2, the third resistor R3, and the fourth resistor R4 connected in parallel to be 6 ohm. More specifically, the controller 230 may turn on some second switches 221, 222 and 223 capable of connecting the first resistor R1, the second resistor R2, the third resistor R3, and the fourth resistor R4 in parallel among the plurality of second switches 220, and turn off a second switch 224 capable of connecting a fifth resistor R5 in parallel.

According to an embodiment, when the capacity of the first battery 10 is less than the capacity of the second battery 20, the controller 230 may discharge the second battery 20 until the capacity of the second battery 20 is equal to the capacity of the first battery 10. For example, when the capacity of the first battery 10 is 4000 mAh, the voltage of the first battery 10 is 50 V, the capacity of the second battery 20 is 8000 mAh, and the voltage of the second battery 20 is 60 V, the controller 230 may discharge the second battery 20 until the capacity of the second battery 20 is equal to the capacity of the first battery 10. The controller 230 may turn on, among the plurality of first switches 210, the first switch 212 for connecting the second battery 20 to a second resistor R2 connected to the second battery 20, and turn off the plurality of other first switches 211, 213, 214, and 215.

The controller 230 may turn on at least any one second switch of the plurality of second switches 220 to adjust a distribution ratio of discharge current of the second battery 20 applied to the plurality of resistors R.

For example, when the discharge current of the second battery 20 is 10 A and the voltage of the second battery 20 is 60 V, the controller 230 may turn on some of the plurality of second switches 220 and turn off some others to control the plurality of resistor R values to be 60 V/10 A=6 ohm.

For example, when a resistance value of each of the plurality of resistors R is 24 ohm, the controller 230 may connect a first resistor R1, a second resistor R2, a third resistor R3, and a fourth resistor R4 among the plurality of resistors R in parallel to control a total resistance value of the first resistor R1, the second resistor R2, the third resistor R3, and the fourth resistor R4 connected in parallel to be 6 ohm. More specifically, the controller 230 may turn on some second switches 221, 222 and 223 capable of connecting the first resistor R1, the second resistor R2, the third resistor R3, and the fourth resistor R4 in parallel among the plurality of second switches 220, and turn off a second switch 224 capable of connecting a fifth resistor R5 in parallel.

According to an embodiment, when the capacity of the first battery 10 is equal to the capacity of the second battery 20, the controller 230 may discharge the first battery 10 and the second battery 20 at the same time.

The controller 230 may turn on, among the plurality of first switches 210, the first switch 211 for connecting the first battery 10 to the first resistor R1 connected to the first battery 10, turn on the first switch 212 for connecting the second battery 20 to the second resistor R2 connected to the second battery 20, and turn off the plurality of other first switches 213, 214, and 215. In addition, the controller 230 may turn on at least any one second switch of the plurality of second switches 220 to adjust a distribution ratio of discharge currents of the first battery 10 and the second battery 20 applied to the plurality of resistors R.

As described above, the battery management apparatus according to an embodiment disclosed herein may control a discharge rate and heating by using a plurality of resistors connected to one another in parallel.

When a dangerous situation and abnormality occur in some batteries, the battery management apparatus may forcedly discharge an abnormal battery and a nearby battery to prevent a chain accident from occurring on the nearby battery, thereby stably operating the battery swapping station.

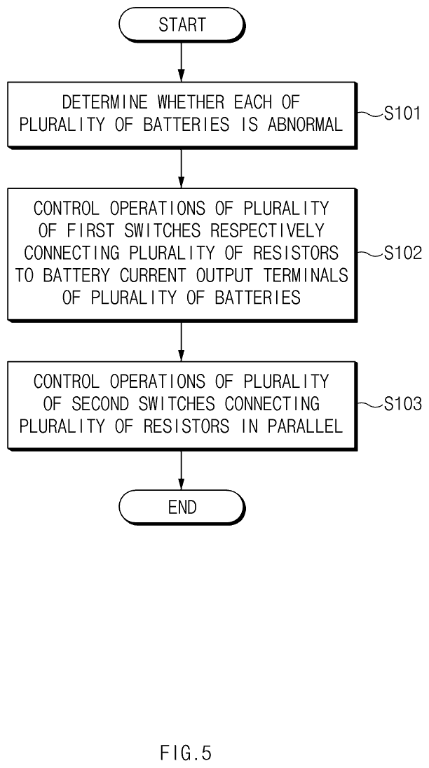

FIG. 5 is a flowchart of an operating method of a battery management apparatus according to an embodiment disclosed herein.

Referring to FIG. 5, the operating method of the battery management apparatus according to an embodiment disclosed herein may include operation S101 of determining whether each of a plurality of batteries is abnormal, operation S102 of controlling operations of a plurality of first switches for connecting a plurality of resistors respectively connected to the plurality of batteries to battery current output terminals of the plurality of batteries, based on whether each of the plurality of batteries is abnormal, and operation S103 of controlling operations of a plurality of second switches for connecting the plurality of resistors in parallel.

Hereinbelow, operations S101 through S103 will be described in detail with reference to FIGS. 1 and 4. The battery management apparatus 200 may be substantially the same as the battery management apparatus 200 described with reference to FIGS. 1 to 4, and thus will be briefly described to avoid redundant description.

In operation S101, the controller 230 may determine whether each of the plurality of batteries 10, 20, 30, 40, and 50 is abnormal.

In operation S101, when the communication unit 240 does not receive a communication signal after an elapse of a specific period from a BMS for any one of the plurality of batteries 10, 20, 30, 40, and 50 and does not receive the communication signal even after repeatedly retrying transmission of a communication signal to the BMS for any one of the plurality of batteries 10, 20, 30, 40, and 50, the controller 230 may determine any one of the plurality of batteries 10, 20, 30, 40, and 50 to be an abnormal battery.

In operation S101, when the communication unit 240 receives an abnormality signal from any one of the plurality of batteries 10, 20, 30, 40, and 50, the controller 230 may determine the any one of the plurality of batteries 10, 20, 30, 40, and 50 to be an abnormal battery.

In operation S101, the controller 230 may receive temperature information of the plurality of batteries 10, 20, 30, 40, and 50 from a plurality of temperature measurement sensors mounted in the battery slot unit 100, and may determine any one of the plurality of batteries 10, 20, 30, 40, and 50 to be an abnormal battery when a temperature of the any one of the plurality of batteries 10, 20, 30, 40, and 50 exceeds a threshold temperature based on the temperature information.

In operation S101, the controller 230 may determine, as the abnormal battery, the first battery 10 among the plurality of batteries 10, 20, 30, 40, and 50 for which an abnormal temperature or an abnormality signal is sensed. The controller 230 may determine at least one second battery 20 related to the first battery 10 determined as the abnormal battery. In operation S101, for example, the controller 230 may determine at least one second battery 20 adjacent to the first battery 10 based on a previously stored arrangement order of the plurality of batteries 10, 20, 30, 40, and 50.

In operation S102, the controller 230 may control operations of the plurality of first switches 210, based on whether the plurality of batteries 10, 20, 30, 40, and 50 are abnormal.

In operation S102, the controller 230 may control operations of the plurality of first switches 210 by comparing the capacity of the first battery 10 with the capacity of the second battery 20.

In operation S103, the controller 230 may control operations of the plurality of second switches 220, based on whether the plurality of batteries 10, 20, 30, 40, and 50 are abnormal.

In operation S103, the controller 230 may turn on at least any one second switch of the plurality of second switches 220 to adjust a distribution ratio of discharge current of the first battery 10 applied to the plurality of resistors R.

In operation S103, for example, when the discharge current of the first battery 10 is 10 A and the voltage of the first battery 10 is 60 V, the controller 230 may turn on some of the plurality of second switches 220 and turn off some others to control the plurality of resistor R values to be 60 V/10 A=6 ohm.

In operation S103, for example, when a resistance value of each of the plurality of resistors R is 24 ohm, the controller 230 may connect a first resistor R1, a second resistor R2, a third resistor R3, and a fourth resistor R4 among the plurality of resistors R in parallel to control a total resistance value of the first resistor R1, the second resistor R2, the third resistor R3, and the fourth resistor R4 connected in parallel to be 6 ohm. In operation S103, more specifically, the controller 230 may turn on some second switches 221, 222 and 223 capable of connecting the first resistor R1, the second resistor R2, the third resistor R3, and the fourth resistor R4 in parallel among the plurality of second switches 220, and turn off a second switch 224 capable of connecting a fifth resistor R5 in parallel.

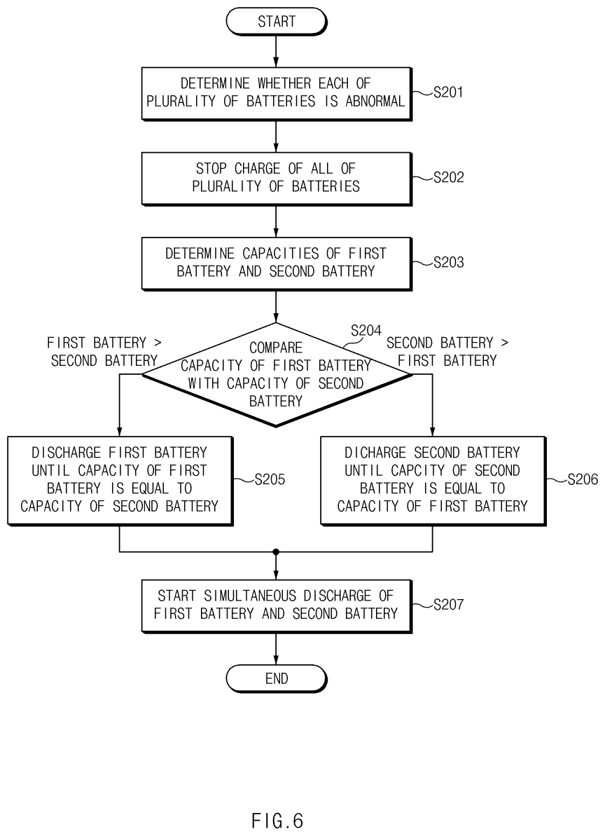

FIG. 6 is a flowchart showing an operating method of a battery management apparatus, according to another embodiment disclosed herein.

Referring to FIG. 6, the operating method of the battery management apparatus according to an embodiment disclosed herein may include operation S201 of determining whether each of a plurality of batteries is abnormal, operation S202 of stopping charge of all of the plurality of batteries, operation S203 of determining capacities of a first battery and a second battery, operation S204 of comparing the capacity of the first battery with the capacity of the second battery, operation S205 of discharging the first battery until the capacity of the first battery is equal to the capacity of the second battery, operation S206 of discharging the second battery until the capacity of the second battery is equal to the capacity of the first battery, and operation S207 of starting simultaneous discharge of the first battery and the second battery.

Hereinbelow, operations S201 through S207 will be described in detail with reference to FIGS. 1 and 4. The battery management apparatus 200 may be substantially the same as the battery management apparatus 200 described with reference to FIGS. 1 to 4, and thus will be briefly described to avoid redundant description.

In operation S201, the controller 230 may determine whether each of the plurality of batteries 10, 20, 30, 40, and 50 is abnormal.

In operation S201, the controller 230 may determine, as the abnormal battery, the first battery 10 among the plurality of batteries 10, 20, 30, 40, and 50 for which an abnormal temperature or an abnormality signal is sensed. In operation S201, the controller 230 may determine at least one second battery 20 related to the first battery 10 determined as the abnormal battery. In operation S201, for example, the controller 230 may determine at least one second battery 20 adjacent to the first battery 10 based on a previously stored arrangement order of the plurality of batteries 10, 20, 30, 40, and 50.

In operation S202, the controller 230 may stop charge of the plurality of batteries 10, 20, 30, 40, and 50. In operation S202, the controller 230 may transmit a charge stop signal for the first battery 10 determined as the abnormal battery and the second battery 20 adjacent to the first battery 10 to the charger 300.

In operation S203, the controller 230 may calculate the capacities of the first battery 10 determined as the abnormal battery and the second battery 20. In operation S203, the controller 230 may receive battery data through communication with a BMS for the first battery 10 and a BMS for the second battery 20. Herein, the battery data may include, for example, a voltage of the battery, a voltage of a battery cell of the battery, a fault signal, an internal temperature of the battery, etc. In operation S203, the controller 230 may calculate capacities of the first battery 10 and the second battery 20 based on the battery data of the first battery 10 and the second battery 20.

In operation S204, the controller 230 may compare the capacity of the first battery 10 with the capacity of the second battery 20.

In operation S205, the controller 230 may control operations of the plurality of first switches 210 by comparing the capacity of the first battery 10 with the capacity of the second battery 20.

In operation S205, when the capacity of the first battery 10 exceeds the capacity of the second battery 20, the controller 230 may discharge the first battery 10 until the capacity of the first battery 10 is equal to the capacity of the second battery 20. In operation S205, for example, when the capacity of the first battery 10 is 8000 mAh, a voltage of the first battery 10 is 60 V, the capacity of the second battery 20 is 4000 mAh, and a voltage of the second battery 20 is 50 V, the controller 230 may discharge the first battery 10 until the capacity of the first battery 10 is equal to the capacity of the second battery 20. In operation S205, the controller 230 may turn on, among the plurality of first switches 210, the first switch 211 for connecting the first battery 10 to the first resistor R1 connected to the first battery 10, and turn off the plurality of other first switches 212, 213, 214, and 215.

In operation S206, when the capacity of the first battery 10 is less than the capacity of the second battery 20, the controller 230 may discharge the second battery 20 until the capacity of the second battery 20 is equal to the capacity of the first battery 10. In operation S206, for example, when the capacity of the first battery 10 is 4000 mAh, the voltage of the first battery 10 is 50 V, the capacity of the second battery 20 is 8000 mAh, and the voltage of the second battery 20 is 60 V, the controller 230 may discharge the second battery 20 until the capacity of the second battery 20 is equal to the capacity of the first battery 10. In operation S206, the controller 230 may turn on, among the plurality of first switches 210, the first switch 212 for connecting the second battery 20 to the second resistor R2 connected to the second battery 20, and turn off the plurality of other first switches 211, 213, 214, and 215.

In operation S207, when the capacity of the first battery 10 is equal to the capacity of the second battery 20, the controller 230 may discharge the first battery 10 and the second battery 20 at the same time.

In operation S207, the controller 230 may turn on, among the plurality of first switches 210, the first switch 211 for connecting the first battery 10 to the first resistor R1 connected to the first battery 10, turn on the first switch 212 for connecting the second battery 20 to the second resistor R2 connected to the second battery 20, and turn off the plurality of other first switches 213, 214, and 215. In operation S207, in addition, the controller 230 may turn on at least any one second switch of the plurality of second switches 220 to adjust a distribution ratio of discharge currents of the first battery 10 and the second battery 20 applied to the plurality of resistors R.

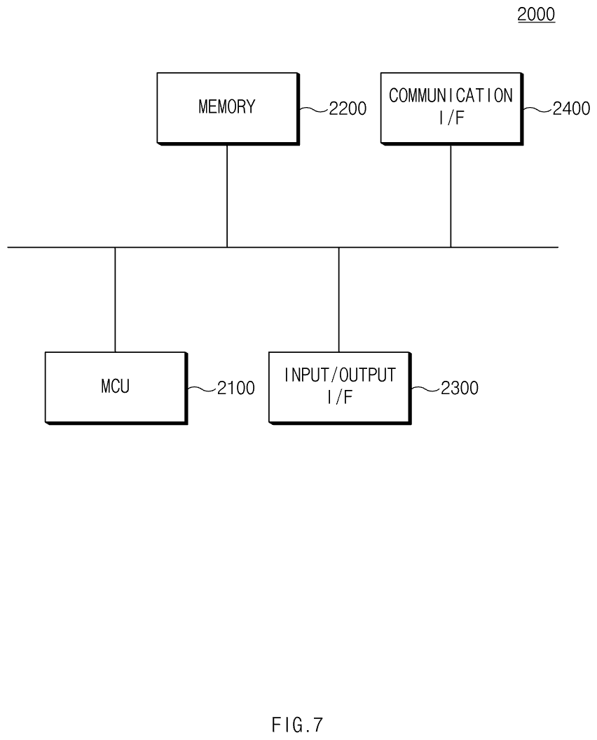

FIG. 7 is a block diagram showing a hardware configuration of a computing system for performing an operating method of a battery management apparatus, according to an embodiment disclosed herein.

Referring to FIG. 7, a computing system 2000 according to an embodiment disclosed herein may include an MCU 2100, a memory 2200, an input/output I/F 2300, and a communication I/F 2400.

The MCU 2100 may be a processor that executes various programs (e.g., a battery capacity calculation program) stored in the memory 2200, processes various data including an SOC, an SOH, etc., of a plurality of battery cells through these programs, executes functions of the battery management apparatus 200 described above with reference to FIG. 1, or executes the operating method of the battery management apparatus described with reference to FIG. 4.

The memory 2200 may store various programs regarding SOH calculation of the battery cell, cell target determination, etc. Moreover, the memory 2200 may store various data such as SOC data, SOH data, etc., of each battery cell.

The memory 2200 may be provided in plural, depending on a need. The memory 2200 may be volatile memory or non-volatile memory. For the memory 2200 as the volatile memory, random access memory (RAM), dynamic RAM (DRAM), static RAM (SRAM), etc., may be used. For the memory 2200 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 2200 are merely examples and are not limited thereto.

The input/output I/F 2300 may provide an interface for transmitting and receiving data by connecting an input device (not shown) such as a keyboard, a mouse, a touch panel, etc., and an output device such as a display (not shown), etc., to the MCU 2100.

The communication I/F 2400, which is a component capable of transmitting and receiving various data to and from a server, may be various devices capable of supporting wired or wireless communication. For example, a program for SOH calculation of the battery cell or target determination or various data, etc., may be transmitted and received to and from a separately provided external server through the communication I/F 2400.

As such, an operating method of a battery management apparatus according to an embodiment disclosed herein may be recorded in the memory 2200 and executed by the MCU 2100.

The above description is merely illustrative of the technical idea of the present disclosure, and various modifications and variations will be possible without departing from the essential characteristics of embodiments of the present disclosure by those of ordinary skill in the art to which the embodiments disclosed herein pertains.

Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present disclosure.

### EXPLANATION OF REFERENCE NUMERALS

10, 20, 30, 40, 50: Plurality of Batteries
1000: Battery Swapping Station
100: Battery slot unit
110, 120, 130, 140: Plurality of Battery Slots
T1, T2, T3, T4, T5: Plurality of Temperature Measurement Sensors
200: Battery Management Apparatus
R1: First Resistor
R2: Second Resistor
R3: Third Resistor
R4: Fourth Resistor
R5: Fifth Resistor
211, 212, 213, 214, 215: Plurality of First Switches
221, 222, 223, 224: Plurality of Second Switches
230: Controller
240: Communication Unit
300: Charger
2000: Computing System
2100: MCU
2200: Memory
2300: Input/Output I/F
2400: Communication I/F

1. A battery management apparatus comprising:
a plurality of resistors connected to a plurality of batteries, respectively;
a plurality of first switches configured to connect the plurality of resistors to output terminals of the plurality of batteries, respectively;
a plurality of second switches configured to connect the plurality of resistors to each other in parallel; and
a controller configured to determine whether each battery of the plurality of batteries is abnormal, and control operations of the plurality of first switches and the plurality of second switches based on whether each battery of the plurality of batteries is abnormal.

2. The battery management apparatus of claim 1, wherein the plurality of resistors are connected to the plurality of batteries in series, respectively, and
wherein the plurality of second switches are connected to one another in series.

3. The battery management apparatus of claim 2, further comprising a communication unit configured to receive an abnormality signal of the plurality of batteries from a battery management system (BMS) for each battery of the plurality of batteries,
wherein the controller is further configured to determine a first battery for which an abnormality signal is sensed and at least one second battery connected to the first battery among the plurality of batteries, based on the abnormality signal.

4. The battery management apparatus of claim 3, wherein the controller is further configured to obtain temperature information of each battery of the plurality of batteries from a plurality of temperature measurement sensors that measure temperatures of the plurality of batteries, respectively, and determine a first battery for which an abnormal temperature is sensed and at least one second battery connected to the first battery among the plurality of batteries, based on the temperature information.

5. The battery management apparatus of claim 4, wherein the controller is further configured to determine the at least one second battery adjacent to the first battery based on an arrangement order of each battery of the plurality of batteries, when sensing the abnormal temperature or the abnormality signal of the first battery among the plurality of batteries.

6. The battery management apparatus of claim 4, wherein the controller is further configured to calculate a capacity of the first battery and a capacity of the at least one second battery and compare the capacity of the first battery with the capacity of the second battery to control operations of the plurality of first switches and the plurality of second switches.

7. The battery management apparatus of claim 6, wherein, when the capacity of the first battery exceeds the capacity of the at least one second battery, the controller is further configured to turn on a first switch among the plurality of first switches for connecting the first battery to a resistor connected to the first battery and turn on at least one second switch among the plurality of second switches.

8. The battery management apparatus of claim 6, wherein, when the capacity of the first battery is less than the capacity of the at least one second battery, the controller is further configured to turn on a first switch among the plurality of first switches for connecting the at least one second battery to a resistor connected to the at least one second battery and turn on at least one second switch among the plurality of second switches.

9. An operating method of a battery management apparatus, the operating method comprising:
determining whether each battery of a plurality of batteries is abnormal;
controlling operations of a plurality of first switches for connecting a plurality of resistors connected to the plurality of batteries to battery current output terminals of the plurality of batteries, respectively, based on whether each battery of the plurality of batteries is abnormal; and
controlling operations of a plurality of second switches connecting the plurality of resistors in parallel, respectively.

10. The operating method of claim 9, wherein the determining of whether each battery of the plurality of batteries is abnormal comprises:
receiving an abnormality signal of the plurality of batteries from a battery management system (BMS) for each battery of the plurality of batteries; and
determining a first battery for which the abnormality signal is sensed and at least one second battery connected to the first battery among the plurality of batteries, based on the abnormality signal.

11. The operating method of claim 10, wherein the determining of whether each battery of the plurality of batteries is abnormal further comprises:
obtaining temperature information of the plurality of batteries from a plurality of temperature measurement sensors that measure temperatures of the plurality of batteries, respectively; and
determining a first battery for which an abnormal temperature is sensed and at least one second battery connected to the first battery among the plurality of batteries, based on the temperature information.

12. The operating method of claim 11, wherein the determining of whether each battery of the plurality of batteries is abnormal further comprises determining the at least one second battery adjacent to the first battery based on an arrangement order of the plurality of batteries, when sensing the abnormal temperature or the abnormality signal of the first battery among the plurality of batteries.

13. The operating method of claim 12, wherein the determining of whether each battery of the plurality of batteries is abnormal further comprises calculating a capacity of the first battery and a capacity of the at least one second battery and comparing the capacity of the first battery with the capacity of the at least one second battery to control operations of the plurality of first switches and the plurality of second switches.

14. The operating method of claim 13, wherein the controlling of the operations of the plurality of first switches for connecting the plurality of resistors connected to the plurality of batteries to the battery current output terminals of the plurality of batteries, based on whether each battery of the plurality of batteries is abnormal comprises, when the capacity of the first battery exceeds the capacity of the at least one second battery, turning on a first switch among the plurality of first switches for connecting the first battery to a resistor connected to the first battery, and
the controlling of the operations of the plurality of second switches connecting the plurality of resistors in parallel comprises turning on at least one second switch among the plurality of second switches.

15. The operating method of claim 13, wherein the controlling of the operations of the plurality of first switches for connecting the plurality of resistors connected to the plurality of batteries to the battery current output terminals of the plurality of batteries, based on whether each battery of the plurality of batteries is abnormal further comprises, when the capacity of the first battery is less than the capacity of the at least one second battery, turning on a first switch among the plurality of first switches for connecting the second battery to a resistor connected to the second battery, and
the controlling of the operations of the plurality of second switches connecting the plurality of resistors in parallel comprises turning on at least one second switch among the plurality of second switches.
